(19) United States
(12) Patent Application Publication
(10) Pub. No.: US 2005/0199990 A1
(43) Pub. Date: Sep. 15, 2005

(54) Protection of plastic detector's packages against shortwave light destruction

(75) Inventor: Eugeniusz A. Woloszczuk, San Jose, CA (US)

Correspondence Address: Barnes & Thornburg, Suite 900, 750 17th Street, N.W., Washington, DC, 20006, US

(73) Assignee: Intersil Americas Inc.

(21) Appl. No.: 10/799,767

(22) Filed: Mar. 15, 2004

(51) Int. Cl. G01N 21/00; H01L 23/02

(52) U.S. Cl. 257/680

(57) ABSTRACT

A housing having a plastic window and a protective coating on the window permitting transmission of light of a wavelength of around 400 nanometers through the window portion while protecting the window portion from deterioration. The protective coating protects against ozone produced by the air ionization caused by received light. The package includes an optical detector, and the package and optical detector are part of an optical reader in an optical storage system.

### BACKGROUND AND SUMMARY OF THE DISCLOSURE

The present disclosure relates generally to optical detectors and, more specifically, for a package for optical detectors.

Optical detectors are used in many environments and in many situations. They are generally designed to receive light waves, either generically or of a specific wavelength. They are used to detect the presence or absence of light waves. They are generally used in optical storage devices, where they receive reflected light from a laser source. Optical storage systems generally include Compact Discs (CDs) and Digital Versatile Discs (DVDs). These optical storage systems generally use short wavelength laser sources. Presently, optical detector systems, for wavelength around 400 nanometers, use a glass window of the housing to improve optical to electrical response and to avoid window's deterioration by short wavelength light. However, the glass window increases the overall price of the packaging.

The use of plastic windows provides an economic advantage over the glass windows of the housing. It has been found that the short wavelength laser sources cause deterioration of the surface of the plastic window.

The present disclosed housing has a plastic window and a protective coating on the window permitting transmission of light of a wavelength of around 400 nanometers through the window portion while protecting the window portion from deterioration. The protective coating protects against ozone produced by the air ionization caused by received light. The package includes an optical detector, and the package and optical detector are part of an optical reader in an optical storage system.

These and other aspects of the present disclosure will become apparent from the following detailed description of the disclosure, when considered in conjunction with accompanying drawings.

### BRIEF DESCRIPTION OF DRAWINGS

FIG. 1 is a schematic of an optical storage system.

FIG. 2 is a cross-section of a photo-detector incorporating the principles of the present disclosure.

### DETAILED DESCRIPTION OF THE PREFERRED EMBODIMENTS

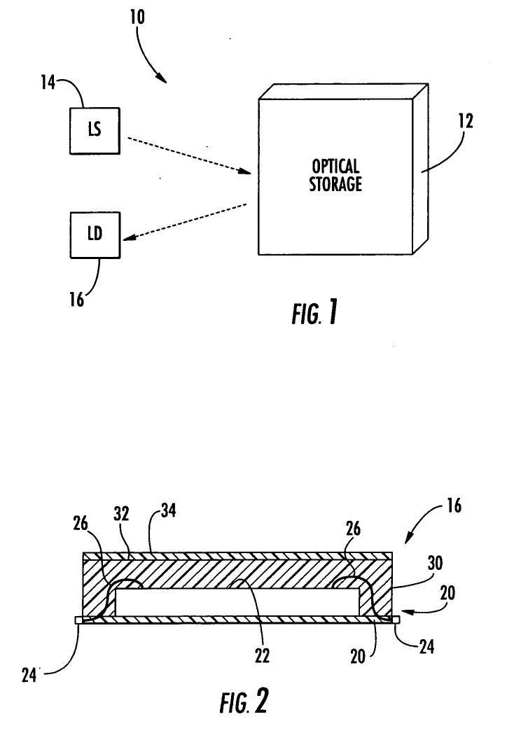

An optical storage system 10 is illustrated in FIG. 1 as having an optical storage device 12, a light source 14 and a light detector 16. For the optical storage system 10 being a CD or a DVD, the light source 14 is a laser generally having a wavelength in the range from around 400 nanometers to 780 nanometers. The light from the light source 14 is directed to and reflects from the optical storage device 12 and is received by the light detector 16. This information light is then further processed.

Light detectors for optical storage application are presently built two ways. One method is to attach a silicon chip with detector and associated amplifier to a lead-frame. Wire bonding connects the silicon chip to pins on the lead-frame. The silicon chip and wires are then encapsulated using transparent plastics. The detectors look similar to other non-optical integrated circuits with two general differences; namely, the optical package is transparent, and the plastic housing melts at the soldering temperature used for nontransparent package of integrated circuits.

Another method is to attach the silicone chip to a temperature resistant substrate, like alumina ceramics, FR4 (PCB) or similar material, which includes metalized pads for soldering to the optical system's PCB. After wire-bond connections, the top of this assembly is covered by a transparent plastic layer, protecting the silicon chip and wire-bond areas. Such a light detector 16 is illustrated in FIG. 2 as including a substrate 20 having an integrated circuit 22, including a light detector mounted thereon. Metalized pads 24 on the substrate 20 are connected by wires 26 to bonding pads on the integrated circuit 22. A plastic protective layer or housing 30 encapsulates the integrated circuit 22 and wires 26 and includes a window portion 32 provided in the cover 22. A protective coating 34 is provided over the plastic window 32.

The plastic housing 30 and window 32 may be clear epoxy molding compound or equivalent transparent plastic. One example is HYSOL® MG97. The protective coating 34 may be one or more of the following materials: silicon oxide SiO₂ and aluminum nitrate. For some housing materials or plastic windows, the process for depositing or applying the protective coating may be limited in temperature and duration. One low temperature method of applying SiO₂ is a pulsed plasma-PICVD, which allows coatings at room temperature. The protective coating 34 would have a thickness in the range of ¼ to ½ of the wavelength of the light source. In case it is necessary for optical performance at specific wavelengths, anti-reflective coating may be added over the protective coating by the same PICVD process. The housing 30 may also be clear epoxy mold compound or other well-known housing material. Although the housing 30 has been described as totally transparent with an integral window 32, the window 32 can be of a different material than the housing 30. The window 32 is just to signify the location for the reception of the light to be detected by the detector portion of the integrated circuit 22.

The short wavelength lasers produce ozone by air ionization around the light beam. The ozone oxidizes the surface of the window. This oxidizing dulls the surface and affects the transmission quality of the window 32. Thus, protective coating 34 is of a material sufficient to not be affected by the ozone created by the laser light. Although these coatings are well known for their optical transparency and have been used to coat sunglasses, they have not been used in optical detectors, much less optical detectors for optical storage device systems.

Although the present disclosure has been described and illustrated in detail, it is to be clearly understood that this is done by way of illustration and example only and is not to be taken by way of limitation. The scope of the present disclosure is to be limited only by the terms of the appended claims.

1. A package for an optical detector comprising:
a plastic window portion of the housing; and
a protective coating on the window portion permitting transmission of light of a wavelength of around 400 nanometers through the window portion while protecting the window portion from deterioration by produced ozone which is produced by the light of a wavelength of around 400 nanometers.

2. The package of claim 1, wherein the plastic window is clear epoxy mold compound.

3. The package of claim 1, wherein the protective coating is one of silicone oxide and aluminum nitrate.

4. The package of claim 1, wherein the protective coating has a thickness in the range of ¼ to ½ of the wavelength of the light.

5. The package of claim 1, including an optical detector in the package.

6. The package of claim 5, wherein the package and optical detector are an optical reader in an optical storage system.

7. The package of claim 1, wherein the light is in the range of around 400 to 780 nanometers.

8. A package for an optical detector comprising:
a plastic window portion of the housing; and
means on the window portion permitting transmission of light of a wavelength of around 400 nanometers through the window portion while protecting the window portion from deterioration produced by ozone which is produced by the light of a wavelength of around 400 nanometers.

9. The package of claim 8, wherein the plastic window is clear epoxy molding compound.

10. The package of claim 8, wherein the means is one of silicon oxide and aluminum nitrate.

11. The package of claim 8, wherein the means has a thickness in the range of ¼ to ½ of the wavelength of the light.

12. The package of claim 8, including an optical detector in the package.

13. The package of claim 12, wherein the package and optical detector are an optical reader in an optical storage system.

14. The package of claim 8, wherein the light is in the range of around 400 to 780 nanometers.

15. An integrated circuit comprising:
a semiconductor chip including a light sensitive device;
a transparent plastic layer over the light sensitive device; and
a protective coating on the plastic layer selected from silicon oxide and aluminum nitrate.

16. The integrated circuit of claim 15, wherein the protective coating has a thickness in the range of ¼ to ½ of the wavelength of the light to be received.

17. The integrated circuit of claim 15, wherein the light sensitive device is an optical detector in a package.

18. The integrated circuit of claim 18, wherein the package and optical detector are an optical reader in an optical storage system.

19. The integrated circuit of claim 15, wherein the light to be received is in the range of around 400 to 780 nanometers.

20. A package for an optical detector comprising:
a plastic window portion of the housing; and
a protective coating on the window portion permitting transmission of light of a wavelength of around 400 nanometers through the window portion while protecting the window portion from deterioration.
